(19) United States
(12) Patent Application Publication
(10) Pub. No.: US 2026/0280482 A1
(43) Pub. Date: Sep. 17, 2026

(54) SPANDREL WINDOW UNIT

(71) Applicants: Christopher COLE, West Perth (AU); Douglas John Charles HUNT, Dudley Park (AU)

(72) Inventors: Christopher COLE, West Perth (AU); Douglas John Charles HUNT, Dudley Park (AU)

(21) Appl. No.: 19/668,662

(22) Filed: May 5, 2026

Related U.S. Application Data
(63) Continuation of application No. PCT/AU2024/051174, filed on Nov. 6, 2024.

(30) Foreign Application Priority Data
Nov. 6, 2023 (AU) 2023903559
Mar. 6, 2024 (AU) 2024900587

(51) Int. Cl. H02S 40/34; H02S 20/26

(52) U.S. Cl. CPC H02S 40/345; H02S 20/26

(57) ABSTRACT

The present disclosure provides a spandrel window unit for a constructed structure. The spandrel window unit may include a laminated structure comprising a first optically transmissive panel, a second panel, a photovoltaic cell between the first and second panels, and a structural layer configured to reduce deformation when temperature exceeds a threshold value. A junction box may be connected to the laminated structure and may include an electrical unit electrically connected to the photovoltaic cell. The junction box may comprise a housing with a base, side walls, and a cavity. An electrical unit may be positioned in the cavity and spaced from the base for thermal isolation. A cover may be connected to the laminated structure and junction box, configured to inhibit separation when temperature exceeds the threshold. A heat sink with outwardly extending fins may be thermally connected to the electrical unit for heat dissipation.

### CROSS-REFERENCE TO RELATED APPLICATIONS

This application is a continuation of International Application No. PCT/AU2024/051174, filed Nov. 6, 2024 which claims priority to Australian Patent Application Nos. 2023903559 filed Nov. 6, 2023, and 2024900587 filed Mar. 6, 2024, all of which are incorporated herein by reference in their entireties.

### TECHNICAL FIELD

The disclosure relates to a spandrel window unit or cladding window unit for a constructed structure. In particular, this disclosure relates to a spandrel window unit or cladding window unit that includes a photovoltaic system.

### BACKGROUND

Systems that generate electricity using renewable energy sources are increasingly being used to provide electricity to constructed structures such as buildings, thereby reducing their dependence on non-renewable electricity sources. For example, solar electricity generation systems are deployed on both new and existing constructed structures to reduce the extent to which these constructed structures are reliant on non-renewable electricity sources. Solar electricity generation systems may be installed on the rooftop of a constructed structure or integrated into elements of the façade of the constructed structure, such as windows.

Fires can cause significant damage to constructed structures. A fire can weaken, compromise or destroy load-bearing structures, exterior or interior walls, ceilings, flooring, windows, doors or electrical equipment of the constructed structure. Windows and other glass panels are particularly vulnerable in a fire as the heat of the fire can cause the windows and glass panels to deform or break. Further, the application of an extinguishing agent on windows and glass panels can cause rapid temperature changes within the windows and glass panels, increasing the likelihood that they will deform or break. Electrical equipment is also vulnerable in a fire. Heat, flames, smoke and extinguishing agents used to extinguish fires can cause significant damage to electrical equipment. This damage may cause electrical short circuits or overloading which can present significant risks to occupants of the constructed structure and emergency response personnel, in addition to increasing the risk of fire growth.

It is to be understood that, if any prior art publication is referred to herein, such reference does not constitute an admission that the publication forms a part of the common general knowledge in the art, in Australia or any other country.

### SUMMARY

In some embodiments, there is provided a spandrel window unit or a cladding window unit for a constructed structure. The spandrel window unit may comprise a laminated structure. The laminated structure may comprise a first panel. The first panel may be optically transmissive. The laminated structure may comprise a second panel. The laminated structure may comprise a photovoltaic cell. The photovoltaic cell may be between the first panel and the second panel. The laminated structure may comprise a structural layer. The structural layer may be configured to reduce deformation of the laminated structure when a temperature of the laminated structure exceeds a threshold value. The spandrel window unit may comprise a junction box. The junction box may be connected to the laminated structure. The junction box may comprise an electrical unit. The electrical unit may be electrically connected to the photovoltaic cell. The spandrel window unit may comprise a cover. The cover may be connected to the laminated structure and the junction box. The cover may be configured to inhibit separation of the junction box and the laminated structure when the temperature of the laminated structure exceeds the threshold value.

In some embodiments, the first panel comprises a borosilicate glass pane.

In some embodiments, the second panel comprises a glass pane.

In some embodiments, the second panel includes a hole.

In some embodiments, a photovoltaic cell electrical connector extends through the hole. The photovoltaic cell electrical connector may be electrically connected to an electrode of the photovoltaic cell.

In some embodiments, the structural layer is between the photovoltaic cell and the second panel.

In some embodiments, the structural layer comprises a structural element. A first adhesive may bond the structural element to the second panel.

In some embodiments, the first adhesive fills one or more voids of the structural element.

In some embodiments, a second adhesive bonds the structural element to the photovoltaic cell.

In some embodiments, the junction box comprises a heat sink.

In some embodiments, the heat sink is thermally connected to the electrical unit.

In some embodiments, the junction box comprises a thermal pad between the heat sink and the electrical unit. The thermal pad may enable heat transfer between the electrical unit and the heat sink.

In some embodiments, the heat sink comprises outwardly extending fins or protrusions. The heat sink may have a first portion and a second portion, and the outwardly extending fins or protrusions in the first portion may extend further than in the second portion. The junction box may have an inclined wall and in use the first portion of the heat sink may be positioned above the inclined wall. In an embodiment, the cover comprises: a frame having a base configured for adhesion to the laminate structure; a plurality of longitudinal channels configured to receive the outwardly extending fins or protrusions therein such that at least a portion of the outwardly extending fins or protrusions can extend through the frame. The frame may surround a perimeter of the junction box when the frame is adhered to the laminate structure.

In an embodiment, an outer portion of the heat sink includes a flat section configured to thermally mate with a third panel spaced from the laminate structure. In use, heat from the heat sink may be transferred to the third panel. In an embodiment, the spandrel window unit further comprises a third panel spaced from the laminate structure such that a cavity is formed therebetween. The junction box may be placed in the cavity and the flat section of the heat sink contacts the third panel such that the heat sink is thermally connected to the heat sink. The third panel may include vacuum insulation glass.

In some embodiments, a third adhesive bonds the cover to the second panel and the photovoltaic cell.

In some embodiments, the cover includes a number of holes. One or more of the outwardly extending fins or protrusions may extend through a respective hole of the cover.

In some embodiments, a number of channels are defined between the outwardly extending fins or protrusions. Intumescent tape may be provided in each channel.

In some embodiments, intumescent tape is provided on one or more edge surfaces of the laminated structure.

In some embodiments, the junction box comprises a housing. An electrical cable may extend through the housing of the junction box and away from the junction box. The electrical cable may be covered by a sheath.

In some embodiments, one or more of the structural layer and the cover comprises fibreglass.

In some embodiments, the spandrel window unit further comprises a fill material that is at least partially within the junction box. The fill material may be configured to inhibit moisture ingress into the laminated structure from the junction box. The fill material may be thermally isolating.

In some embodiments, the fill material comprises silicone.

In an embodiment, the junction box comprises a thermal fuse configured to trip at or around a threshold temperature, thereby electrically isolating the photovoltaic cell from the rest of the junction box and the electrical network of the connected structure. The threshold temperature may be 300° C. or higher.

In an embodiment, the electrical unit is spaced from a floor of the junction box such that in use the electrical unit is spaced from and thermally isolated from the laminate structure.

In an embodiment, intumescent material is applied to a rear surface of the laminated structure.

An embodiment provides a junction box for a spandrel window unit having a photovoltaic cell associated with one or more panels of the spandrel window unit, the junction box comprising:
a housing having a base, side walls extending from the base and a cavity defined by the base and side walls;
an electrical unit positioned in the cavity and spaced from the base such that in use the electrical unit is thermally isolated from a panel to which the housing contacts, the electrical unit being configured to be electrically connected to the photovoltaic cell.

An embodiment further comprises a heat sink configured to be thermally connected to the electrical unit such that heat generated by the electrical unit can be transferred to the heat sink. The heat sink may comprise a tab extending from a side of the heat sink. The housing may comprise a recess in a side wall of the housing or the tab may comprise a recess. The other of the side wall of tab may include a divot that can be received in the recess. This means that the tab of the heat sink may engage with the sidewall of the housing to structurally connect the heat sink to the housing. In an embodiment the recess is on the sidewall of the housing and the tab of the heat sink engages with the recess to structurally connect the heat sink to the housing

The heat sink may comprise outwardly extending fins or protrusions. The heat sink may have a first portion and a second portion, and the outwardly extending fins or protrusions in the first portion may extend further than in the second portion. One of the side walls may be an inclined wall and the first portion of the heat sink may be configured to be positioned above the inclined wall.

An embodiment further comprises a cover, the covering including: a frame having a base configured for adhesion to a panel to which the housing contacts; a plurality of longitudinal channels configured to receive the outwardly extending fins or protrusions therein such that at least a portion of the outwardly extending fins or protrusions can extend through the frame. The frame may be dimensioned to surround a perimeter of the junction box.

An embodiment further comprises a cover that includes a number of holes; and one or more of the outwardly extending fins or protrusions extends through a respective hole of the cover.

In an embodiment, a number of heat sink channels are defined between the outwardly extending fins or protrusions; and intumescent tape is provided in each channel.

In an embodiment, an outer portion of the heat sink includes a flat section configured to thermally mate with a panel such that, in use, heat from the heat sink can be transferred to the panel.

An embodiment further comprises a thermal pad contacting the electrical unit and the heat sink to assist with transfer of heat from the electrical unit to the heat sink. The thermal pad may be moulded to have a skirt to shape around the electrical unit.

In an embodiment, the electrical unit includes a thermal fuse and/or a diode.

### BRIEF DESCRIPTION OF THE DRAWINGS

Embodiments will now be described, by way of example only, with reference to the accompanying non-limiting drawings, in which:

FIG. 1 is a plan view of a section plane of a spandrel window unit, according to an embodiment of the disclosure.

FIG. 2 shows a bottom perspective view of the spandrel window unit of FIG. 1, with a cover of the spandrel window unit hidden.

FIG. 3 is an exploded view of a junction box for a spandrel window unit, according to an embodiment.

FIG. 4 illustrates an isometric view of a junction box mounted on a laminate structure, according to an embodiment.

FIG. 5 shows a cross-sectional view of the junction box and laminate structure of FIG. 4.

FIG. 6 depicts a section view of a junction box for a spandrel window unit, according to an embodiment.

FIGS. 7 and 8 show isometric views of the junction box of FIG. 6 in different states.

FIG. 9 illustrates an isometric view of a junction box for a spandrel window unit, according to an embodiment.

FIG. 10 presents an isometric view of a double-glazed spandrel window unit, according to an embodiment.

FIG. 11 depicts a cross-sectional view of the double-glazed spandrel window unit of FIG. 10.

FIG. 12 illustrates an isometric view of a junction box for a spandrel window unit, according to an embodiment.

FIG. 13 presents a side view of the junction box of FIG. 12.

FIG. 14 shows an exploded isometric view of a junction box, according to an embodiment.

FIG. 15 depicts orthogonal views of the junction box components of FIG. 14.

FIG. 16 illustrates an isometric view of a junction box for a double-glazed spandrel window unit, according to an embodiment.

FIG. 17 presents a cross-sectional view of the double-glazed spandrel window unit of FIG. 16.

### DETAILED DESCRIPTION

Spandrel window units or cladding window units can be used as part of a façade of a constructed structure. Spandrel window units or cladding window units are typically opaque or reflective and are used to conceal structural elements of the constructed structure that lie behind the spandrel window unit once installed. Photovoltaic systems can be integrated into window units such as spandrel window units or cladding window units and used to provide electricity to the associated constructed structure. Through this disclosure, the terms “spandrel window unit” and “cladding window unit” can be used interchangeably to refer to a non-vision window used to cover or conceal structural elements associated with the constructed structure.

The present disclosure relates to a spandrel window unit for use in a constructed structure. The spandrel window unit includes a photovoltaic system. One or more photovoltaic cells of the photovoltaic system are configured to convert incident electromagnetic radiation into an electrical current. The photovoltaic cells obstruct the transmission of incident electromagnetic radiation through the spandrel window unit. The spandrel window unit therefore conceals structural elements of the constructed structure that lie behind it once it is installed.

Fires can cause significant damage to constructed structures and the risks associated with this are particularly applicable to window units that incorporate photovoltaic systems. The heat produced by a fire can cause the glass panes of the window unit to deform, crack or shatter. The window unit itself may deform, crack or shatter under these conditions. Further, the electrical components of the photovoltaic system can be damaged or destroyed by such a fire. If this occurs, the electrical connection between the photovoltaic cells of the photovoltaic system and the electrical network of the constructed structure may be broken.

If exposed to incident electromagnetic radiation, photovoltaic cells continue to generate electrical current during a fire, even when their connection to the electrical network of the constructed structure is broken. The electrodes of the photovoltaic cells are open circuits under these conditions, with the electrical energy generated by the photovoltaic cells remaining within the photovoltaic cells or being dissipated as heat. This may present a number of hazards to emergency response personnel or cleanup personnel. Emergency response personnel and cleanup personnel may encounter live electrical systems when attempting to control the fire or access the constructed structure's interior. The damaged or exposed electrical connections of the photovoltaic cells can create electric arcs which can ignite nearby materials, potentially exacerbating the spread of the fire.

Window units of constructed structures can also be damaged when a fire is being extinguished. Fires are often extinguished by the application of an extinguishing agent. The application of the extinguishing agent can induce a relatively rapid temperature change in the glass panels of a window unit, increasing the likelihood that they will crack or break.

The spandrel window unit of the present description includes a laminated structure that includes a first panel that is optically transmissive, a second panel and a photovoltaic cell between the first panel and the second panel. The laminated structure includes a structural layer that is configured to reduce deformation of the laminated structure when a temperature of the laminated structure exceeds a threshold value (e.g., during a fire). The spandrel window unit also includes a cover that is connected to the laminated structure and a junction box of the spandrel window unit. The cover is configured to inhibit separation of the junction box and the laminated structure when the temperature of the laminated structure exceeds the threshold value. The inclusion of the structural layer and the cover in the spandrel window unit reduces the likelihood that the spandrel window unit will break apart during a fire or during the process of extinguishing the fire, thereby reducing the associated risks to emergency response personnel and cleanup personnel. One or both of the structural layer and the cover may also inhibit heat transfer. In other words, these features may increase the heat resistance of the spandrel window unit, thereby decreasing the likelihood that the spandrel window unit will be destroyed or fail during a fire.

### Spandrel Window Unit 100

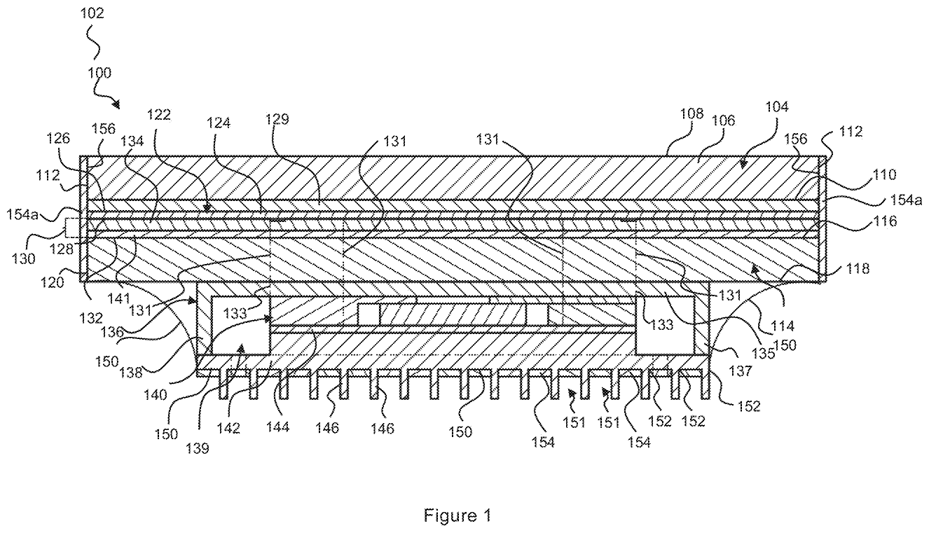

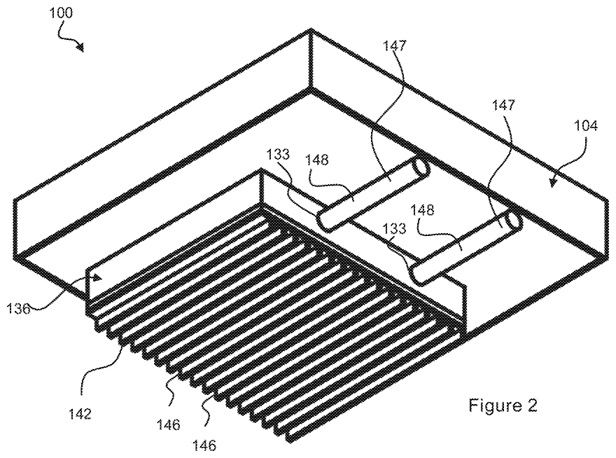

FIG. 1 shows a plan view of a section plane 102 of a spandrel window unit 100, according to an embodiment of the disclosure. FIG. 2 shows a bottom perspective view of the spandrel window unit 100 with a number of features of the spandrel window unit 100 hidden. The spandrel window unit 100 is configured to be used in a constructed structure. Examples of constructed structures include buildings, bridges, power plants and trains. The spandrel window unit 100 may form part of a façade of the constructed structure.

The spandrel window unit 100 comprises a laminated structure 104. The laminated structure 104 is formed using a lamination process. The laminated structure 104 comprises a first panel 106. The first panel 106 comprises a first major face 108 and a second major face 110. The first major face 108 is planar. The second major face 110 is planar. The first major face 108 is an outer face of the spandrel window unit 100. The first major face 108 is parallel to the second major face 110. The first panel 106 comprises a plurality of edge faces 112. The illustrated first panel 106 comprises four edge faces 112. In particular, the first panel 106 comprises two pairs of parallel edge faces 112. It will be appreciated that in some embodiments, the first panel 106 may comprise a different number of edge faces 112. The surface area of each of the first major face 108 and the second major face 110 is greater than the surface area of each edge face 112. The first major face 108 and the second major face 110 are each orthogonal to the edge faces 112.

At least part of the first panel 106 is optically transmissive. For the purposes of this disclosure, a material or component being optically transmissive indicates that the material or component enables incident electromagnetic radiation to pass through with minimal absorption, scattering or reflection. Thus, at least part of the first panel 106 enables incident electromagnetic radiation to pass through with minimal absorption, scattering or reflection. In the illustrated embodiment, the entire first panel 106 is optically transmissive. The first panel 106 may be considered an outer panel of the spandrel window unit 100.

The first panel 106 comprises a glass pane. In particular, the first panel 106 comprises a borosilicate glass pane. In the illustrated embodiment, the first panel 106 is in the form of a borosilicate glass pane. It will, however, be appreciated that in some embodiments, the first panel 106 may comprise one or more features in addition to a glass pane, such as a frame, an optical filter etc. The first panel 106 may be ablated. That is, one or more of the faces of the first panel 106 may be ablated. The first panel 106 may be coloured. For example, the first panel 106 may comprise or be in the form of coloured glass. In some embodiments, the first panel 106 comprises or is in the form of coloured borosilicate glass. The first panel 106 may be coloured by an ablation process. The first panel 106 may be coloured by a ‘frit’ process whereby dots or similar are printed onto the first panel 106. The frit may be a ceramic frit. The first panel 106 may be configured to reflect, refract and/or diffract certain electromagnetic wavelengths. In particular, the first panel 106 may be configured to reflect, refract and/or diffract certain electromagnetic wavelengths whilst being configured to enable other electromagnetic wavelengths to transmit therethrough.

The laminated structure 104 comprises a second panel 114. The second panel 114 comprises a first major face 116 and a second major face 118. The first major face 116 is planar. The second major face 118 is planar. The first major face 116 is parallel to the second major face 118. The second panel 114 comprises a plurality of edge faces 120. The illustrated second panel 114 comprises four edge faces 120. In particular, the second panel 114 comprises two pairs of parallel edge faces 120. It will be appreciated that in some embodiments, the second panel 114 may comprise a different number of edge faces 120. The surface area of each of the first major face 116 and the second major face 118 is greater than the surface area of each edge face 120. The first major face 116 and the second major face 118 are each orthogonal to the edge faces 120.

At least part of the second panel 114 is optically transmissive. That is, at least part of the second panel 114 enables incident electromagnetic radiation to pass through with minimal absorption, scattering or reflection. In the illustrated embodiment, the entire second panel 114 is optically transmissive. It will be appreciated, however, that in some embodiments, at least part of the second panel 114 is not optically transmissive. The second panel 114 may be considered an inner panel of the spandrel window unit 100.

The second panel 114 comprises a glass pane. In the illustrated embodiment, the second panel 114 is in the form of a glass pane. In some embodiments, the second panel 114 may comprise one or more features in addition to a glass pane, such as a frame, an optical filter etc. In some embodiments, the second panel 114 comprises one or more of a polymer, a metal and a ceramic. That is, the second panel 114 may be a polymer panel, a metal panel or a ceramic panel. In such cases, the second panel 114 may not comprise glass. The second panel 114 is parallel to the first panel 106. The second panel 114 may be ablated. That is, one or more of the faces of the second panel 114 may be ablated. The second panel 114 may be coloured. For example, the second panel 114 may comprise or be in the form of coloured glass. In some embodiments, the second panel 114 comprises or is in the form of coloured borosilicate glass. The second panel 114 may be coloured by an ablation process.

The spandrel window unit 100 comprises a photovoltaic system 122. The photovoltaic system 122 is configured to convert incident electromagnetic radiation into an electrical current. Specifically, the photovoltaic system 122 is configured to convert at least some of the electromagnetic radiation that is incident to the first major face 108 of the first panel 106 into an electrical current following the transmission of this electromagnetic radiation through the first panel 106. The electrical current generated by the photovoltaic system 122 can be supplied to an electrical network of the constructed structure.

The photovoltaic system 122 comprises a photovoltaic cell 124. The photovoltaic cell 124 is laminated between the first panel 106 and the second panel 114. The laminated structure 104 may be said to comprise the photovoltaic cell 124. The photovoltaic cell 124 is configured to convert at least some of the electromagnetic radiation that is incident to the first major face 108 of the first panel 106 into an electrical current following the transmission of this electromagnetic radiation through the first panel 106. The photovoltaic cell 124 comprises a light receiving side 126. The photovoltaic cell 124 comprises a back side 128. The light receiving side 126 faces towards the first panel 106. The back side 128 may also receive light, such as if the photovoltaic cell 124 is bifacial. The back side 128 faces away from the first panel 106. The back side 128 faces towards the second panel 114.

The photovoltaic system 122 comprises one or more electrical connectors (not shown). The electrical connectors may be referred to as photovoltaic cell electrical connectors. The photovoltaic cell electrical connectors are configured to enable the photovoltaic cell 124 to be electrically connected to one or more other electrical components. The photovoltaic cell electrical connectors may comprise or be in the form of one or more of a photovoltaic cell tab, an electrical wire and a ribbon cable. In the illustrated embodiment, the photovoltaic cell electrical connectors are electrically connected to a respective electrode of the photovoltaic cell 124.

The photovoltaic system 122 is bonded to the first panel 106. In particular, a first adhesive 129 bonds the photovoltaic cell 124 to the first panel 106. The first adhesive 129 is a high temperature adhesive. In other words, the first adhesive 129 is a thermally resistant adhesive. The first adhesive 129 is optically transmissive. The first adhesive 129 may comprise of be formed from Polyvinyl Butyral (PVB). The first adhesive 129 may comprise or be formed from Ethylene Vinyl Acetate (EVA). The first adhesive 129 may form a layer of the laminated structure 104. This layer may be referred to as a first adhesive layer. The first adhesive layer is between the first panel 106 and the photovoltaic cell 124.

The laminated structure 104 comprises a structural layer 130. The structural layer 130 is configured to reduce deformation of the laminated structure 104. In particular, the structural layer 130 is configured to reduce deformation of the laminated structure 104 when a temperature of the laminated structure exceeds a threshold value. The threshold value is associated with the temperature at which the laminated structure 104 may reach during a structural fire. In particular, the threshold value is associated with the temperature at which one or both of the first panel 106 and the second panel 114 will deform, crack or break during a structural fire. The threshold value may be the lower of the temperature at which the first panel 106 will deform, crack or break and the temperature at which the second panel 114 will deform, crack or break. In some embodiments, the threshold value may be the temperature at which one of the adhesives used in the manufacturing of the spandrel window unit 100 fails. In some embodiments, the threshold value may be 400° C., 500° C., 600° C., 700° C., 800° C., 900° C., 1,000° C., 1,100° C., 1,200° C. or above 1,200° C. The threshold value may be within 400° C. and 1,200° C., 500° C. and 1,200° C., 600° C. and 1,200° C., 700° C. and 1,200° C., 800° C. and 1,200° C., 900° C. and 1,200° C., 1,000° C. and 1,200° C. or 1,100° C. and 1,200° C. The threshold value may be above 400° C., 500° C., 600° C., 700° C., 800° C., 900° C., 1,000° C., 1,100° C. or 1,200° C.

The structural layer 130 is between the photovoltaic cell 124 and the second panel 114. The first major face 116 of the second panel 114 faces the structural layer 130. The back side 128 of the photovoltaic cell 124 faces the structural layer 130.

The structural layer 130 comprises a structural element 141. The structural element 141 is in the form of a mat 141. In particular, the structural element 141 is in the form of a fibrous mat 141. The structural element 141 comprises a number of voids. In other words, the fibrous mat 141 comprises a number of voids. The structural layer 130 comprises fibreglass. Specifically, the structural element 141 comprises fibreglass. In the illustrated embodiment, the structural element 141 is in the form of a fibreglass mat. In other words, the fibrous mat 141 is in the form of a fibreglass mat. The structural element 141 comprises a plurality of fibres. The fibres are glass fibres. The structural layer 130 may also act or is an electrical insulator. The structural layer may also act as or is a thermal insulator. That is, the structural layer 130 may be configured to inhibit heat transfer therethrough.

The structural layer 130 comprises a second adhesive 132. The second adhesive 132 bonds the structural element 141 to the second panel 114. In other words, the structural element 141 is bonded to the second panel 114. The second adhesive 132 is a high temperature adhesive. In other words, the second adhesive 132 is a thermally resistant adhesive.

The second adhesive 132 may be considered to form a sub-layer of the structural layer 130. This layer may be referred to as a second adhesive layer. Alternatively, the second adhesive 132 may be considered to form a layer of the laminated structure 104. The second adhesive 132 at least partially fills one or more of the voids of the structural element 141. Specifically, the second adhesive 132 fills a number of the voids of the fibrous mat 141.

The structural layer 130 comprises a third adhesive 134. The third adhesive 134 bonds the structural element 141 to the photovoltaic cell 124. In other words, the structural element 141 is bonded to the photovoltaic cell 124. The third adhesive 134 is a high temperature adhesive. In other words, the third adhesive 134 is a thermally resistant adhesive. The third adhesive 134 may be the same as the second adhesive 132. The third adhesive 134 may be different to the second adhesive 132.

The third adhesive 134 may be considered to form a sub-layer of the structural layer 130. This layer may be referred to as a third adhesive layer. Alternatively, the third adhesive 134 may be considered to form a layer of the laminated structure 104. The third adhesive 134 at least partially fills one or more of the voids of the structural element 141. Specifically, the third adhesive 134 fills a number of the voids of the fibrous mat 141.

A number of holes 131 extend through at least part of the laminated structure 104. In the illustrated embodiment, two holes 131 extend through part of the laminated structure 104. The holes 131 extend through at least part of each of the structural layer 130 and the second panel 114. The photovoltaic cell electrical connectors extend through the holes 131. In particular, the photovoltaic cell electrical connectors extend through the holes 131, away from the photovoltaic cell 124. One photovoltaic cell electrical connector may extend through each hole 131.

The spandrel window unit 100 comprises a junction box 136. The junction box 136 comprises a housing 138. The housing 138 comprises a first wall 135. The first wall 135 is parallel to the second panel 114. The housing 138 comprises a number of lateral walls 137. The lateral walls 137 are transverse to the first wall 135. In the illustrated embodiment, the lateral walls 137 are orthogonal to the first wall 135. The housing 138 defines an internal volume 139. In particular, the first wall 135 and the lateral walls 137 of the housing define the internal volume 139 that is bound by an opening defined by the lateral walls 137. The housing 138 comprises a polymer. In the illustrated embodiment, the housing 138 comprises a thermally resistant polymer.

The junction box 136 comprises an electrical unit 140. The electrical unit 140 is mounted to the housing 138. The electrical unit 140 comprises a number of electrical components. For example, the electrical unit 140 comprises one or more diodes. The electrical unit 140 may include a diode. The electrical unit 140 may be a diode. One or more of the electrical components may be mounted to the housing 138. The electrical unit 140 is electrically connected to the photovoltaic cell 124. In other words, one or more of the electrical components of the junction box 136 is electrically connected to the photovoltaic cell 124. The electrical unit 140 is electrically connected to the photovoltaic cell 124 via the photovoltaic cell electrical connectors.

The junction box 136 comprises a fuse. In particular, the electrical unit 140 comprises the fuse. The fuse is a thermal fuse. The fuse is electrically connected to the photovoltaic cell 124. The fuse is configured to trip at or near a fuse threshold temperature. The tripping of the fuse electrically isolates the photovoltaic cell 124 from the junction box 136. That is, the fuse tripping electrically isolates the photovoltaic cell 124 from the electrical unit 140. The photovoltaic cell 124 is therefore isolated from the electrical network of the constructed structure in the event that the fuse trips.

The fuse threshold temperature may be 300° C. The fuse threshold temperature may be about 300° C. In some embodiments, the fuse threshold temperature is 200° C., 400° C., 500° C., 600° C., 700° C., 800° C., 900° C. or 1,000° C. The fuse threshold temperature may be within 200° C. and 400° C., within 100° C. and 500° C., within 200° C. and 500° C., within 200° C. and 600° C., within 200° C. and 700° C. or within 200° C. and 800° C. The fuse threshold temperature may be above 100° C., 200° C., 300° C., 400° C., 500° C., 600° C., 700° C., 800° C., 900° C. or 1,000° C.

The junction box 136 comprises a number of junction box holes 133. The junction box holes 133 extend through the housing 138. The junction box holes 133 fluidly connect the internal volume 139 of the junction box 136 and an external environment of the junction box 136. A number of the junction box holes 133 extend through the first wall 135. These junction box holes 133 are aligned with the holes 131 that extend through the laminated structure 104. In particular, these junction box holes 131 are coaxially aligned with the holes 131 that extend through the laminated structure 104. In the illustrated embodiment, the junction box 136 comprises a junction box hole 133 for each hole 131 that extends through the laminated structure 104. That is, the junction box 136 comprises two junction box holes 133 that are coaxially aligned with the holes 131 of the laminated structure. The photovoltaic cell electrical connectors extend through the junction box holes 133 that are aligned with the holes 131 that extend through the laminated structure 104. The photovoltaic cell electrical connectors extend through the first wall 135 into the internal volume 139 of the housing 138 to connect to the electrical unit 140.

The junction box 136 also comprises a number of additional junction box holes 133. Specifically, the junction box 136 includes a number of junction box holes 133 in the lateral walls 137 of the housing 138.

The junction box 136 comprises a heat sink 142. The heat sink 142 is thermally connected to the electrical unit 140. The heat sink 142 is configured to dissipate heat transferred to the heat sink 142 from the electrical unit 140 to the surrounding environment. The junction box 136 comprises a thermal pad 144. The thermal pad 144 is between the heat sink 142 and the electrical unit 140. The thermal pad 144 is in contact with the heat sink 142. The thermal pad 144 is in contact with the electrical unit 140. The thermal pad 144 enables heat transfer between the electrical unit 140 and the heat sink 142. In other words, the thermal pad 144 enables heat transfer between the electrical components of the junction box and the heat sink 142. The heat sink 142 comprises outwardly extending fins 146. The illustrated heat sink 142 comprises a plurality of fins 146. Each fin 146 extends between a base and a free end. The fins 146 extend away from the thermal pad 144. A number of channels 151 are defined between the fins 146. Each pair of adjacent fins 146 defines a respective channel 151 therebetween.

The spandrel window unit 100 comprises a number of electrical cables 147 (see FIG. 2). The electrical cables 147 may facilitate an electrical connection between the photovoltaic system 122 and the constructed structure's electrical network. The illustrated spandrel window unit 100 comprises two electrical cables 147. The electrical cables 147 extend through the housing 138 of the junction box 136 and away from the junction box 136. In particular, the electrical cables 147 extend through the junction box holes 133 of the lateral walls 137 of the housing 138. Each electrical cable 147 extends through a respective junction box hole 133 of the lateral walls 137 of the housing 138. The electrical cables 147 are electrically connected to the electrical unit 140. In other words, the electrical cables 147 are electrically connected to one or more of the electrical components of the junction box 136.

One or more of the electrical cables 147 may be covered by a sheath 148. In the illustrated embodiment, each electrical cable 147 is covered by a respective sheath 148. The sheath(s) 148 are thermal insulators. The sheath(s) are electrical insulators. The sheath(s) 148 comprise fibreglass. The sheath(s) 148 may be in the form of fibreglass sheets.

The junction box 136 is connected to the laminated structure 104. Specifically, the junction box 136 is bonded to the second panel 114. An adhesive bonds the junction box 136 to the second panel 114. The adhesive may be a high temperature adhesive. In other words, the adhesive may be a thermally resistant adhesive. The adhesive bonds the first wall 135 of the junction box 136 to the second major face 118 of the second panel 114.

The spandrel window unit 100 comprises a cover 150. The cover 150 is connected to the laminated structure 104. In the illustrated embodiment, the cover 150 is bonded to the laminated structure 104. A fourth adhesive may bond the cover 150 to the laminated structure 104. The fourth adhesive may be a high temperature adhesive. In other words, the fourth adhesive may be a thermally resistant adhesive. The cover 150 is bonded to the second panel 114 of the laminated structure 104. In particular, the cover 150 is bonded to the second major face 118 of the second panel 114.

The cover 150 is connected to the junction box 136. In the illustrated embodiment, the cover 150 is bonded to the junction box 136. The adhesive that bonds the cover 150 to the laminated structure 104 may also bond the cover 150 to the junction box 136. In other words, the fourth adhesive may bond the cover 150 to the junction box 136 and the second panel 114. Alternatively, separate adhesives may be used. That is, the adhesive used to bond the cover 150 to the junction box 136 may be different to the adhesive used to bond the cover 150 to the second panel 114.

The cover 150 is configured to inhibit separation of the junction box 136 and the laminated structure 104. In particular, the cover 150 is configured to inhibit separation of the junction box 136 and the laminated structure 104 in the case where the spandrel window unit 100 is exposed to a fire. Thus, the cover 150 is configured to inhibit separation of the junction box 136 and the laminated structure 104 when the temperature of the laminated structure 104 exceeds the threshold value.

The cover 150 may inhibit heat transfer from the environment of the spandrel window unit 100 to the junction box 136 and the second panel 114. In other words, the cover 150 may insulate the junction box 136 and the second panel 114. The cover 150 comprises fibreglass. The cover 150 may be in the form of a fibreglass sheet.

The cover 150 comprises a number of holes 152. The holes 152 of the cover 150 may be referred to as cover holes. The cover 150 comprises a hole 152 for each fin 146 of the junction box 136. One or more of the fins 146 extends through a respective hole 152 of the cover 150. In the illustrated embodiment, each fin 146 extends through a respective hole 152 of the cover 150. The cover 150 is bonded to the heat sink 142 between each fin 146. The fourth adhesive bonds the cover 150 to the heat sink 142. The cover 150 may also comprise one or more holes 152 through which the electrical cables 147 extend. A shape of the holes 152 is typically complementary to a shape of each fin 146. For example, if the 146 is elongate, a respective hole 152 is also elongate.

The cover 150 is an electrical insulator. The cover 150 comprises fibreglass. Specifically, the cover 150 is a fibreglass sheet. The cover 150 may comprise a different material. For example, the cover 150 may comprise one or more of Kevlar and a ceramic.

The spandrel window unit 100 comprises intumescent tape 154. The intumescent tape 154 is provided within each channel 151 of the heat sink 142. The intumescent tape 154 is applied to an exterior surface of the cover 150, between the respective fins 146 defining the particular channel 151. The intumescent tape 154 is also provided on one or more edge surfaces 156 of the laminated structure 104. In the illustrated embodiment, the intumescent tape 154 is provided on each edge surface 156 of the laminated structure 104. That is, the intumescent tape 154 is applied to the edge faces 112 of the first panel and the edge faces 120 of the second panel 114, in addition to edge faces of the structural layer 130.

The spandrel window unit 100 comprises a fill material (not shown). The fill material may be provided within one or both of the junction box 136 and the holes 131 that extend through the laminated structure 104. The fill material is configured to inhibit moisture ingress into the laminated structure 104 from the junction box 136. In particular, the fill material is configured to inhibit moisture ingress towards the photovoltaic cell 124. The fill material comprises silicone. The fill material may be injected into the junction box 136 and/or the holes 131 that extend through the laminated structure 104.

### High Temperature and Thermal Shock Functionality of the Spandrel Window Unit 100

The spandrel window unit 100 described herein is configured such that the extent to which it is damaged in a fire and the extent to which it creates hazards in a fire are reduced. Specifically, the structural integrity of the spandrel window unit 100, when exposed to high temperatures as is the case in fires and when exposed to relatively rapid changes in temperature, for example, when fire extinguishing agents are applied to the spandrel window unit 100 to extinguish a fire, are improved.

If a fire occurs in a constructed structure that includes the spandrel window unit 100, the spandrel window unit 100 may be exposed to high temperatures (for example, temperatures up to or exceeding 1,200° C.), flames, smoke and extinguishing agents. A number of the features of the spandrel window unit 100 described herein provide advantages under these conditions.

As described herein, the first panel 106 is in the form of a borosilicate glass pane. Borosilicate glass has a high temperature tolerance when compared to other glasses (such as soda-lime glass). Borosilicate glass is less likely to shatter at higher temperatures and when exposed to thermal shock than other glasses and is generally stronger than other glasses. The use of borosilicate glass in the first panel 106 therefore increases the structural integrity of the first panel 106. That is, the first panel 106 can withstand greater forces and both greater temperatures and more rapid temperature changes than other glasses are capable of withstanding, without deforming, cracking or shattering. Therefore, if a fire occurs in a constructed structure that includes the spandrel window unit 100, the first panel 106 is less likely to deform, crack or shatter than other optically transmissive panels. Further, if the spandrel window unit 100 is experiences thermal shock (e.g., when an extinguishing agent is applied to extinguish the fire), it is less likely to deform, crack or shatter. This reduces the likelihood that the first panel 106 will be damaged in a fire and, if it is damaged, it reduces the extent of the damage and the additional hazards that result from damage of the first panel 106 (e.g., glass debris, exposure of the photovoltaic cell 124 etc.).

The structural layer 130 also improves the structural integrity of the spandrel window unit 100. Specifically, the structural layer 130 reduces the likelihood that the spandrel window unit 100 will break apart during a fire or if it is exposed to thermal shock when the fire is extinguished. As described herein, the structural layer 130 comprises a structural element 141 that is bonded to the photovoltaic cell 124 and the second panel 114. When exposed to a fire or the associated heat, there is a risk that the first panel 106, the photovoltaic cell 124 and/or the second panel 114 will deform, break or shatter. If one of these components deforms, breaks or shatters, there is a risk that part of the relevant component will break apart from the rest of the spandrel window unit 100. The structural layer 130 reduces the likelihood that part of, or the entirety of the first panel 106, the photovoltaic cell 124 and/or the second panel 114 will break apart and separate from the rest of the spandrel window unit 100 in a fire or when exposed to thermal shock as the fire is extinguished. If the second panel 114 and/or the photovoltaic cell 124 deforms, breaks or shatters, the structural element 141 remains bonded to the different parts of the broken second panel 114 and/or photovoltaic cell 124. The structural element 141 is thermally resistant and maintains its strength at high temperatures. By maintaining the bonds between the structural element 141 and the photovoltaic cell 124 and the second panel 114, the likelihood that the broken part of the spandrel window unit 100 will separate from the rest of the spandrel window unit 100 is reduced as the broken part will be held in place by the structural element 141 and the associated bond. The structural layer 130 therefore reduces the likelihood that glass or electrical debris will be created during the fire. The structural layer 130 also reduces the likelihood that the photovoltaic cell 124 or the associated electrical components will be damaged in the fire and present an electrical hazard.

The cover 150 also improves the structural integrity of the spandrel window unit 100. The cover 150 reduces the likelihood that the spandrel window unit 100 will break apart during a fire. As described herein, the cover 150 is bonded to the second panel 114 and the junction box 136. The cover 150 partially covers the second panel 114 and the junction box 136 and is a thermal insulator. When exposed to a fire, the cover 150 inhibits the transfer of heat to the second panel 114. The cover 150 also inhibits the transfer of heat to at least some of the junction box 136. For example, the cover inhibits the transfer of heat to the housing 138 of the junction box 136. The cover 150 may therefore increase the time within which the spandrel window unit 100 can be exposed to a fire before being damaged.

When exposed to high temperatures of a fire for an extended period of time, the housing 138 may deform or melt. The bond between the housing 138 and the second panel 114 may also weaken or break. If either of these occurs, the cover 150, which is bonded to both the second panel 114 and the housing 138, will retain the junction box 136 in place. That is, while the bond between the junction box 136 and the second panel 114 may degrade or break, the cover 150 can prevent the junction box 136 from falling away from the laminated structure 104. The cover 150 can therefore reduce the likelihood that debris will be created during the fire. Further, as the cover 150 is an electrical insulator, if the housing 138 is damaged in the fire in a way that would expose the electrical components housed therein, the cover 150 can insulate the electrical components from the environment surrounding the spandrel window unit 100 such that the exposed electrical components present a reduced electrical hazard.

As described herein, the spandrel window unit 100 comprises a number of electrical cables 147 that extend through the housing 138 of the junction box 136 and facilitate an electrical connection between the photovoltaic system 122 and the constructed structure's electrical network. The electrical cables 147 are covered by a sheath 148 that is a thermal insulator and an electrical insulator. When exposed to a fire, the sheath 148 therefore insulates the electrical cables 147 from the heat of the fire and reduces the likelihood that the cables will present an electrical hazard.

The spandrel window unit 100 comprises intumescent tape 154. In the illustrated embodiment, the intumescent tape 154 is provided within each channel 151 of the heat sink 142, being applied to an exterior surface of the cover 150. The intumescent tape 154 is also proved on the edge surfaces 156 of the laminated structure 104. The intumescent tape 154 swells when exposed to the heat and/or flames of a fire. That is, the intumescent tape 154 undergoes a volumetric expansion when exposed to a fire. The intumescent tape 154 is configured to reduce the extent to which the spandrel window unit 100 is damaged in a fire. The intumescent tape 154 between each of the fins 146 of the heat sink 142 can expand to better-insulate the body of the heat sink 142 and the fins 146 from the heat of the fire. The intumescent tape 154a on the edge surfaces 156 of the laminated structure 104 can reduce the extent to which the edge surfaces of the laminated structure 104 are damaged by the fire by providing a physical barrier and acting as a thermal insulator. This may help to prevent thermal damage and degradation of the first adhesive 129 and the second adhesive 132 thereby help to reduce situations such as delamination.

### Alternative Configurations

The photovoltaic system 122 is described herein as comprising a photovoltaic cell 124. It will be appreciated that the photovoltaic system 122 may comprise a plurality of photovoltaic cells 124. In other words, the photovoltaic system 122 may comprise one or more photovoltaic cells 124. Each of the photovoltaic cells 124 may be disposed between the first panel 106 and the second panel 114 as described with reference to the photovoltaic cell 124 above. Each photovoltaic cell 124 may comprise a light receiving side 126 that faces towards the first panel 106 and a back side 128 that faces towards the second panel 114. The photovoltaic cells 124 may be connected in series. The photovoltaic cells 124 may be connected in parallel. The photovoltaic cells 124 may be electrically connected to common photovoltaic cell electrical connectors which pass through the laminated structure 104 and the housing 138 as described herein. The structural element 141 may be bonded to each of the photovoltaic cells 124 as described herein.

The structural element 141 is described herein as comprising fibreglass. Specifically, the structural element 141 is described to be in the form of a fibreglass mat. It will be appreciated that in some embodiments the structural element 141 may comprise one or more other materials. For example, the structural element 141 may comprise Kevlar. The structural element 141 may be in the form of a Kevlar mat. Alternatively, the structural element 141 may comprise a ceramic. The structural element 141 may be in the form of a ceramic mat.

The structural element 141 is shown in FIG. 1 as being positioned between the photovoltaic cell 124 and the second panel 114. However, the structural element 141 may be positioned between the photovoltaic cell 124 and the first panel 112. In such embodiments, voids in the structural element 141 may be of a sufficient size to minimise blocking or shading of the photovoltaic cell 124.

The cover 150 is described herein as comprising fibreglass. Specifically, the cover 150 is described to be in the form of a fibreglass sheet. It will be appreciated that in some embodiments the cover 150 may comprise one or more other materials. For example, the cover 150 may comprise Kevlar. The cover 150 may be in the form of a Kevlar sheet. Alternatively, the cover 150 may comprise a ceramic. The cover 150 may be in the form of a flexible ceramic sheet.

The sheaths 148 are described herein as comprising fibreglass. Specifically, the sheaths 148 are described to be in the form of fibreglass sheets. It will be appreciated that in some embodiments one or more of the sheaths 148 may comprise one or more other materials. For example, one of more of the sheaths 148 may comprise Kevlar. One or more of the sheaths 148 may be in the form of a Kevlar sheet. Alternatively, one or more of the sheaths 148 may comprise a ceramic. One or more of the sheaths 148 may be in the form of a flexible ceramic sheet.

The structural element 141 is described herein as being bonded to the second panel 114 using a second adhesive 132 and being bonded to the photovoltaic cell 124 using a third adhesive 134. In some embodiments, the structural element 141 may be bonded to both the photovoltaic cell 124 and the second panel 114 using the same adhesive. This adhesive may be referred to as the second adhesive. In such a case, the adhesive may be presented on opposing faces of the structural element 141. Alternatively, the adhesive may be presented on one face of the structural element 141, and may pass through the structural element 141 during the lamination process in which the laminated structure 104 is fabricated, via the voids in the structural element 141.

The junction box 136 comprises a fuse as described herein. The fuse is configured to trip at or around the fuse threshold temperature, thereby electrically isolating the photovoltaic cell 124 from the rest of the junction box 136 and the electrical network of the connected structure. As described herein, the spandrel window unit 100 may comprise a plurality of photovoltaic cells 124. In some embodiments, each of the photovoltaic cells 124 may be electrically connected to a common fuse. In some embodiments, each of the photovoltaic cells 124 may be electrically connected to a respective fuse. That is, in these embodiments, the junction box 136 comprises a plurality of fuses. Each fuse of the plurality may be configured to trip at or around the fuse threshold temperature.

The fill material that is provided within one or both of the junction box 136 and the holes 131 that extend through the laminated structure 104 is described herein as silicone. It will be appreciated that in some embodiments, alternative materials or compounds may be used. For example, the fill material may comprise one or more of a foam, a gel, a potting compound and a thermal gap filler.

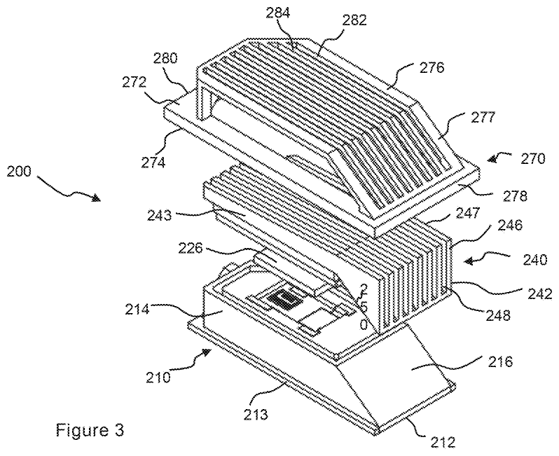

An embodiment of a junction box 200 will now be described with reference to FIG. 3 to FIG. 8. The junction box 200 is used with a spandrel window unit having a photovoltaic cell associated with one or more panels of the spandrel window unit. In an embodiment, the junction box 200 replaces junction box 136 in spandrel window unit 100.

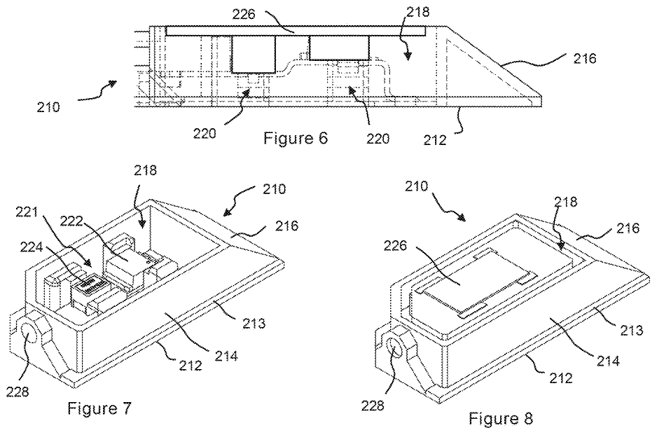

The junction box 200 has a housing 210. The housing 210 has a base 212. Extending away from the base 212 are side walls 214. The side walls 214 are set inboard from a perimeter of the base 212 thereby forming a lip 213. One of the side walls includes inclined wall 216. The inclined wall 216 is positioned as one end wall of the housing 210. The side walls 214 and inclined wall 216 define a cavity 218 therein. An electrical unit 221 is positioned in the cavity 218. In the embodiment shown in FIG. 6 and FIG. 7, the electrical unit 221 includes a diode 222 and thermal fuse 224. In an embodiment, the diode 222 is a high-performance diode.

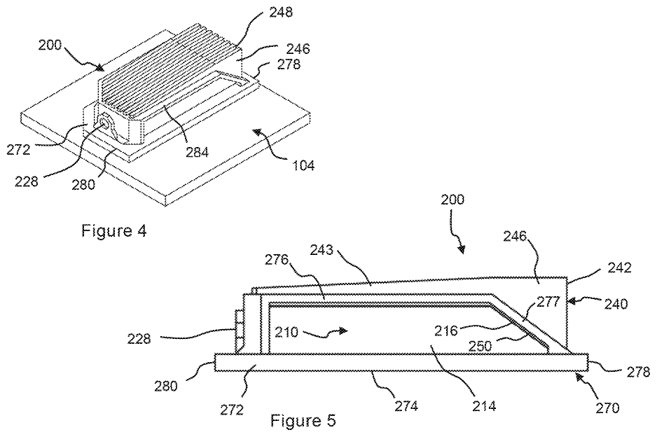

The diode 222 and thermal fuse 224 are positioned in the cavity 218 such that they are spaced from the base 212. Accordingly, a gap 220 is positioned between the base 212 and the diode 222 and thermal fuse 224. The gap 220 helps to thermally isolate the diode 222 and thermal fuse 224 from a panel to which the housing contacts, such as laminate structure 104 as shown in FIG. 4. As already described, the diode 222 and thermal fuse 224 are configured to be electrically connected to the photovoltaic cell 124. The cavity 218 may be filled with a thermally isolating material, such as a silicon material. This thermally isolating material may also help to weather-proof the housing 210 and electrical unit 221.

The housing 210 is also provided with an opening 228 to allow electrical cables connected to the diode 222 and thermal fuse 224 to pass out of the cavity 218 to an external power system. The base 212 is provided with a cutout (not shown) to allow electrical cables to pass from the photovoltaic cell 124 to the diode 222 and thermal fuse 224.

The junction box 200 also includes a heat sink 240 configured to be thermally connected to the electrical unit such that heat generated by the electrical unit can be transferred to the heat sink 240. In the embodiment shown in FIG. 3 to FIG. 8, a thermal pad 226 is positioned between the electrical unit 221 and the heat sink 240. The thermal pad 226 helps to transfer heat from the electrical unit 221 to the heat sink 240. The thermal pad 226 may include a thermal paste and is not limited to a solid structure but to a thermally conductive substance.

The heat sink 240 has outwardly extending fins 246. The number of fins 246 varies depending on a width of the heat sink 240 and a thickness of each fin 246. A heat sink channel 248 is positioned between adjacent fins 246. The heat sink channels 248 help to increase a surface area of the heat sink 240 to help dissipate heat therefrom. In the embodiment shown in the Figures, the heat sink 240 has a first portion 242 and a second portion 243. The first portion 242 has a ‘wedge’ profile in that an angled floor 250 of the first portion 242 is transverse from a floor or base of the second portion 243. The angled floor 250 is angled to be parallel or approximately parallel to the inclined wall 216. In the assembled state, the angled floor 250 mates with or abuts the inclined wall 216. Because an upper surface 247 of the heat sink 240 is generally planar, the fins 246 extend further away from the angled floor 250 compared to an extension of the fins 246 from the respective floor in the second portion 243. Accordingly, the first portion 242 of the heat sink 240 may be able to dissipate more heat compared to the second portion 243.

In an embodiment, and as shown in FIG. 3 to FIG. 8, the junction box 200 includes a cover in the form of frame 270. The frame 270 is separate to the housing 210 and in use sits over the housing 210. The frame 270 includes a base portion 272 having a first end 278 and a second end 280. A longitudinal direction extends from the first end 278 to the second end 280. The base portion 272 is configured for adhesion to a panel to which the housing contacts. For example, as shown in FIG. 4, the junction box 200 is adhered to the laminate structure 104. Accordingly, the base 272 can be adhered to the laminate structure 104 using a thermally resistant adhesive. The thermally resistant adhesive may retain its adhesiveness at temperatures up to 1000° C. The base portion 272 has an underside 274 to which the thermally adhesive is applied to and which contacts the laminate structure 104.

The frame 270 also has a plurality of longitudinal channels 282 configured to receive the outwardly extending fins 246 therein. This means that at least a portion of the outwardly extending fins 246 can extend through the frame 270 in the assembled state, as shown in FIG. 4 and FIG. 5. The plurality of longitudinal channels 282 are defined or spaced apart by members 284. Accordingly, the frame 270 can be considered as having one or more holes that can receive a respective fin 246. In the assembled state, the members 284 are seated or received in respective heat sink channels 248. The channels 282 are provided in an upper portion 276 of the frame 270. The frame 270 also includes ramped region 277 that extends from the upper portion 276 down to the base portion 272. The ramped region 277 is angled to be parallel to or approximately parallel to the inclined wall 216. Therefore, in the assembled state as shown in FIG. 5, the ramped portion 277 sits approximately parallel to and adjacent to the inclined wall 216.

The frame 270 is dimensioned to surround a perimeter of the housing 210. In an embodiment, the frame 270 hugs or surrounds the lip 213, and may optionally be secured to the lip 213 with ah adhesive. In the assembled state, the frame 270 helps to retain the heat sink 240 and the housing 210 together in the event of a fire due to the thermally resistant adhesive used to secure the frame 270 to the laminate structure 104. In an embodiment, intumescent tape is provided in one or more of the heat sink channels 248 such that the intumescent tape covers the members 284 received or positioned in the heat sink channel 248. The intumescent tape can help to keep the junction box 200 together in a fire and make the junction box 200 more thermally resistant. The frame 270 is formed from a heat-resistant material. For example, the frame 270 may withstand temperatures up to 1000° C. before it begins to fail.

Each of the housing 210, heat sink 240 and cover 270 are separate components that are assembled to form the junction box.

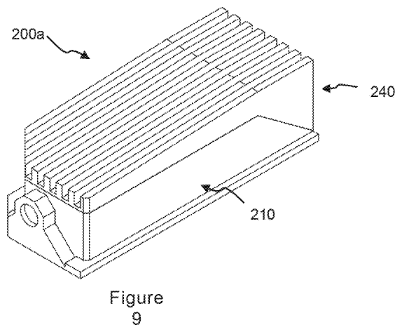

In an alternative embodiment, and as shown in FIG. 9, the junction box 200a does not require the cover 270, for example in situations where the junction box 200a does not need to consider being fire rated. Accordingly, the junction box 200 may be considered as forming a junction box system that includes the housing 210, the heat sink 240 and optionally thermal pad 226. The inclusion of the frame 270 depends on the use of the junction box 200/200a.

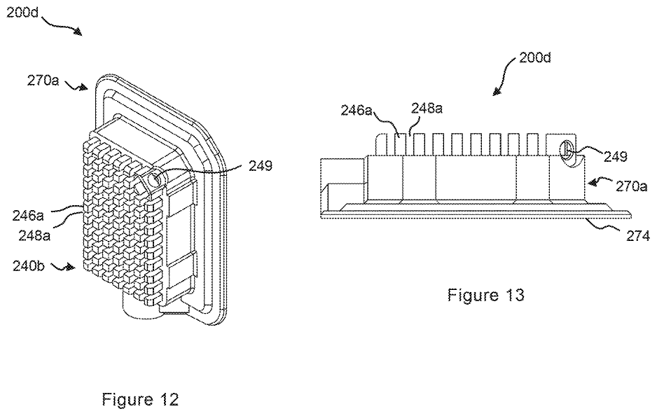

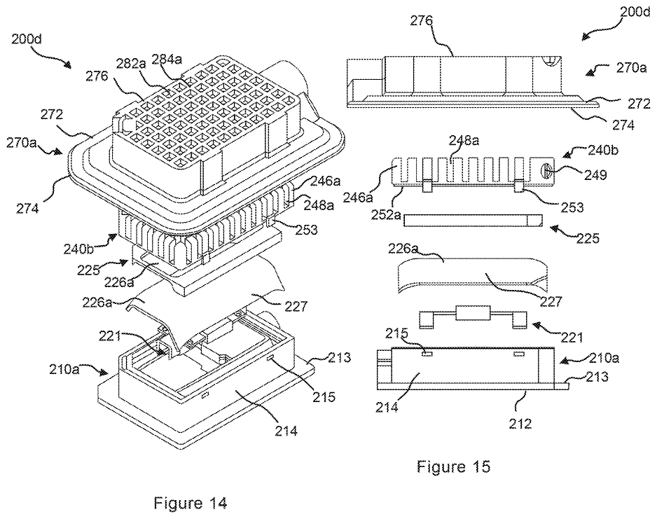

FIGS. 12 to 14 illustrate another embodiment of a junction box 200d for a spandrel window unit. The junction box 200d comprises several components designed to enhance thermal management and structural integrity.

The heat sink 240b features a series of protrusions arranged in a grid-like pattern on its upper surface. These protrusions 246a may help to increase airflow over the heat sink 240b. The protrusions 246a on the heat sink 240b may be considered functional equivalents to the fins 146 described in earlier embodiments. In this way, the protrusions 246a can be referred to as a fin. Both the protrusions 246a and fins 146 serve to increase the surface area of the heat sink, potentially enhancing heat dissipation and airflow. In this context, references to the term “fin” throughout the disclosure may also encompass the protrusions 246a, as they perform a similar thermal management function within the junction box assembly.

The increased surface area and improved air circulation provided by the protrusions 246a may enhance heat dissipation from the junction box 200d. Between the protrusions 246a are heat sink channels 248a, which may further facilitate air movement and heat transfer.

A thermal pad 226a is positioned above the electrical unit 221 within the housing 210a. The thermal pad 226a is designed with a skirt 227 that partially encases the electrical unit 221. This configuration may help to improve heat dissipation from the electrical unit 221 to the heat sink 240b. By surrounding a portion of the electrical unit 221, the thermal pad 226a with its skirt 227 may provide more efficient thermal transfer and potentially protect the electrical components from excessive heat buildup.

The heat sink 240b includes a tab 253a that extends from its side. This tab 253a is designed to engage with a recess 215 in the sidewall 214 of the housing 210a. The recess 215 is positioned in an outer surface of the sidewall 214. This mechanical connection may allow for secure attachment of the heat sink 240b to the housing 210a. In some cases, this connection may help to keep components retained within the junction box 200d during extreme conditions, such as a fire. The secure attachment provided by the tab 253a may contribute to the overall structural integrity of the junction box 200d, potentially reducing the risk of component separation or dislocation under high-stress conditions.

The frame 270a encloses the heat sink 240b and other components, providing additional structural support. The frame 270a includes openings 282a that align with the protrusions 246a of the heat sink 240b, potentially allowing for continued airflow and heat dissipation even when the frame is in place.

The frame 270a and housing 210a may be secured to a substrate, such as a panel of the spandrel window unit, using a thermally resistant adhesive. The underside 274 of the frame 270a is designed to be adhered to the substrate. This thermally resistant adhesive may maintain its bonding properties at elevated temperatures, potentially up to 1000° C. or higher in some cases. The adhesive may be applied to the entire underside 274 of the frame 270a or to specific areas to create a strong and durable bond with the substrate.

Similarly, the base 212 of the housing 210a may also be secured to the substrate using the same or a different thermally resistant adhesive. This configuration may create a robust attachment between the junction box 200d and the panel, potentially helping to maintain the integrity of the assembly during exposure to high temperatures or in the event of a fire. The use of thermally resistant adhesive may also contribute to the overall thermal management of the system by providing a stable connection that can withstand thermal stresses.

These design features of the junction box 200d may work together to provide efficient thermal management and structural stability, potentially enhancing the performance and durability of the spandrel window unit in various conditions.

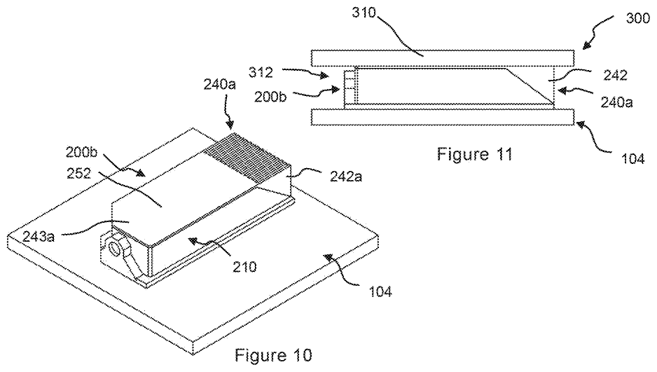

The junction box 200 and 200a are generally configured for use in a single pane spandrel window unit. However, another embodiment of a junction box 200b is shown in FIG. 10 and FIG. 11 is configured for use in a double-glazed spandrel window unit 300. The double-glazed spandrel window unit 300 includes the laminate structure 104 and a second panel 300 spaced from the laminate structure 104. A cavity 312 is formed between the laminate structure 104 and the second panel 300. In an embodiment, the second panel 300 includes vacuum insulated glass. The junction box 200b is configured to be positioned in the cavity 312. A thickness of the double-glazed spandrel window unit 300 may be around 50 mm to 150 mm.

Junction box 200b has the housing 210 the same as junction box 200, but instead uses heat sink 240a. Heat sink 240a is similar to heat sink 240 except that the fins 246 are only present in the first portion 242a. A second portion 243a of the heat sink 240a has an outer portion 250 that includes a flat section 252. As shown in FIG. 11, the flat section 252 is configured to thermally mate with the panel 310 such that, in use, heat from the heat sink 240a can be transferred to the panel 310. This arrangement may help to reduce the amount of heat that is retained in the cavity 312.

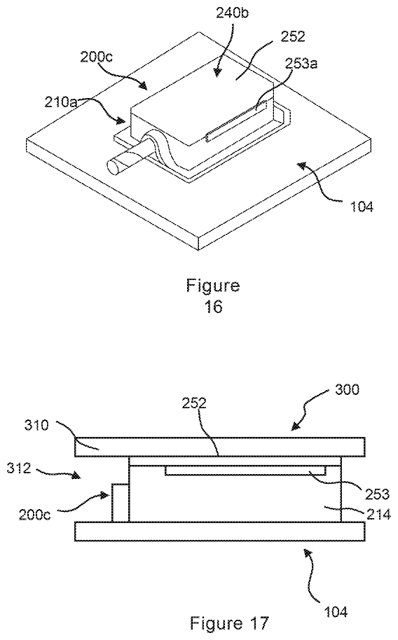

FIGS. 16 and 17 illustrate another embodiment of junction box 200c configured for use in a double-glazed spandrel (or cladding) window unit 300. The junction box 200c shares similarities with junction box 200b, particularly in its overall configuration and thermal management approach.

Like junction box 200b, junction box 200c is positioned within a cavity 312 formed between a laminate structure 104 and a second panel 310. The junction box 200c features a housing 210a with side walls 214, similar to the housing structure of junction box 200b.

A key similarity is the flat heat sink 240b, which includes a flat section 252. This flat section 252 is in direct contact with the underside of the second panel 310, creating a thermal interface between the junction box 200c and the panel. This design is analogous to the flat section 252 in junction box 200b, which also contacts the second panel to facilitate heat transfer.

The flat section 252 of the heat sink 240b may allow for efficient thermal dissipation into the second panel 310, mirroring the functionality of junction box 200b. By maintaining direct contact with the panel, heat generated within the junction box 200c can be effectively transferred to the larger surface area of the second panel 310.

Junction box 200c also incorporates a tab 253a extending from the side, which may serve a similar purpose to the corresponding feature in junction box 200b, potentially aiding in securing the junction box within the cavity 312.

Both designs leverage the second panel 310 as an additional heat dissipation surface, potentially allowing for more efficient cooling of the junction box components. This approach may be particularly beneficial in applications where space is limited, as it utilizes the existing structure of the spandrel window unit for thermal management purposes.

In one or more embodiments, intumescent tape or paint or material may be applied at the edges of laminate structures used with the different embodiments of the junction boxes. The use of the term “tape” also includes intumescent material applied to a surface of the laminate structure, such as by painting. Accordingly, reference to the term “intumescent tape” also includes within its scope intumescent material painted or applied to the laminate structure. This application of intumescent material may provide additional fire protection and thermal insulation for the spandrel window unit. When exposed to high temperatures, the intumescent material expands, potentially creating a barrier that may help to seal gaps and protect the edges of the laminate structure from fire and heat.

The intumescent tape or paint or material may be applied along the perimeter of the laminate structure, covering the exposed edges of the various layers. This application may help to prevent delamination of the structure during fire conditions and may also inhibit the spread of fire or smoke through any small gaps or imperfections at the edges.

In the case of spandrel or cladding windows, which do not necessarily require vision glass, the rear surface of the laminate structure may also be covered with intumescent tape or paint. This additional coverage may provide an extra layer of fire protection and thermal insulation for the entire unit. The intumescent material on the rear surface may expand in the event of a fire, potentially creating an insulating barrier that could help protect the internal components of the spandrel window unit, including the junction box and associated electrical components.

This comprehensive application of intumescent materials may enhance the overall fire resistance of the spandrel window unit, potentially improving its performance in fire safety tests and real-world fire scenarios. The use of intumescent materials in these areas may also contribute to maintaining the structural integrity of the unit during a fire, which may be crucial for the safety of building occupants and first responders.

In the claims that follow and in the preceding description, except where the context requires otherwise due to express language or necessary implication, the word “comprise” or variations such as “comprises” or “comprising” is used in an inclusive sense, i.e., to specify the presence of the stated features but not to preclude the presence or addition of further features in various embodiments of the disclosure.

Modifications and variations as would be apparent to a skilled addressee are deemed to be within the scope of the present invention.

1. A spandrel window unit for a constructed structure, the spandrel window unit comprising:
a laminated structure comprising:
a first panel that is optically transmissive;
a second panel;
a photovoltaic cell between the first panel and the second panel; and
a structural layer that is configured to reduce deformation of the laminated structure when a temperature of the laminated structure exceeds a threshold value;
a junction box that is connected to the laminated structure, the junction box comprising an electrical unit that is electrically connected to the photovoltaic cell; and
a cover that is connected to the laminated structure and the junction box, the cover being configured to inhibit separation of the junction box and the laminated structure when the temperature of the laminated structure exceeds the threshold value.

2. The spandrel window unit of claim 1, wherein the first panel comprises a borosilicate glass pane.

3. A junction box for a spandrel window unit having a photovoltaic cell associated with one or more panels of the spandrel window unit, the junction box comprising:
a housing having a base, side walls extending from the base and a cavity defined by the base and side walls; and
an electrical unit positioned in the cavity and spaced from the base such that in use the electrical unit is thermally isolated from a panel to which the housing contacts, the electrical unit being configured to be electrically connected to the photovoltaic cell.

4. A junction box of claim 3, further comprising a heat sink configured to be thermally connected to the electrical unit such that heat generated by the electrical unit can be transferred to the heat sink.

5. The junction box of claim 4, wherein:
the heat sink comprises a tab extending from a side of the heat sink; and
the housing comprises a recess in a side wall of the housing;
wherein the tab of the heat sink engages with the recess of the housing to structurally connect the heat sink to the housing.

6. The junction box of claim 5, wherein the heat sink comprises outwardly extending fins or protrusions.
